(19) United States
(12) Patent Application Publication
(10) Pub. No.: US 2019/0243178 A1
(43) Pub. Date: Aug. 8, 2019

(54) DISPLAY SUBSTRATE MOTHERBOARD AND METHOD FOR MANUFACTURING DISPLAY SUBSTRATE MOTHERBOARD, DISPLAY SUBSTRATE, DISPLAY PANEL AND DISPLAY DEVICE

(71) Applicants: CHONGQING BOE OPTOELECTRONICS TECHNOLOGY CO., LTD., Chongqing (CN); BOE TECHNOLOGY GROUP CO., LTD., Beijing (CN)

(72) Inventors: Haigang YANG, Beijing (CN); Jingyong HU, Beijing (CN); Wencheng LUO, Beijing (CN); Jungho PARK, Beijing (CN)

(73) Assignees: CHONGQING BOE OPTOELECTRONICS TECHNOLOGY CO., LTD., Chongqing (CN); BOE TECHNOLOGY GROUP CO., LTD., Beijing (CN)

(21) Appl. No.: 16/320,512

(22) PCT Filed: May 14, 2018
(86) PCT No.: PCT/CN2018/086700

§ 371 Date: Jan. 25, 2019

(30) Foreign Application Priority Data
Jun. 5, 2017 (CN) 201710413593.8

(51) Int. Cl. G02F 1/1343; G02F 1/1333; H05K 7/14

(52) U.S. Cl. CPC G02F 1/13439; H05K 7/1427; G02F 1/133351; G02F 1/133308

(57) ABSTRACT

A display substrate motherboard and a method for manufacturing the display substrate motherboard, a display substrate, a display panel and a display device are provided. The method for manufacturing the display substrate motherboard includes: forming a planar electrode layer on the display substrate motherboard; performing a patterning process on the planar electrode layer, and removing a portion of the planar electrode layer to form a plurality of planar electrodes. The portion of the planar electrode layer is located around a predetermined cutting line for the display substrate motherboard. The plurality of planar electrodes is separated from each other. An edge of each of the planar electrodes is parallel to the predetermined cutting line, and a vertical distance between the edge of each of the planar electrodes and the predetermined cutting line is greater than a threshold.

### CROSS-REFERENCE TO RELATED APPLICATIONS

This application is the U.S. national phase of PCT Application No. PCT/CN2018/086700 filed on May 14, 2018, which claims priority to Chinese Patent Application No. 201710413593.8 filed on Jun. 5, 2017, which are incorporated herein by reference in their entireties.

### TECHNICAL FIELD

The present disclosure relates to the field of display technology, and in particular to a display substrate motherboard and a method for manufacturing the display substrate motherboard, a display substrate, a display panel and a display device.

### BACKGROUND

A Thin Film Transistor—Liquid Crystal Display (TFT-LCD) is widely used in various display fields. The liquid crystal display panel generally consists of a color filter substrate, an array substrate, and liquid crystals filled between these two substrates. In order to ensure the display quality of the liquid crystal display panel, it is also required to arrange a column spacer array between the color filter substrate and the array substrate, so that a distance of several microns between the color filter substrate and the array substrate is maintained, thereby ensuring that the liquid crystal is uniformly distributed inside the liquid crystal display panel.

### SUMMARY

In one aspect, the present disclose provides a method for manufacturing a display substrate motherboard including: forming a planar electrode layer on the display substrate motherboard; performing a patterning process on the planar electrode layer, and removing a portion of the planar electrode layer to form a plurality of planar electrodes. The portion of the planar electrode layer is located around a predetermined cutting line for the display substrate motherboard, the plurality of planar electrodes is separated from each other, an edge of each of the planar electrodes is parallel to the predetermined cutting line, and a vertical distance between the edge of each of the planar electrodes and the predetermined cutting line is greater than a threshold.

Optionally, the threshold is 0.1 mm.

The present disclose further provides in some embodiments a display substrate motherboard including: a plurality of planar electrodes arranged on the display substrate motherboard. The plurality of planar electrodes is separated from each other. An edge of each of the planar electrodes is parallel to a predetermined cutting line for the display substrate motherboard, and a vertical distance between the edge of each of the planar electrodes and the predetermined cutting line is greater than a threshold.

Optionally, the threshold is 0.1 mm.

Optionally, the display substrate motherboard is an array substrate motherboard, and the planar electrodes are common electrodes arranged on the array substrate motherboard; or the display substrate motherboard is a color filter substrate motherboard, and the planar electrodes are common electrodes arranged on the color filter substrate motherboard.

The present disclose further provides in some embodiments a display substrate. A vertical distance between an edge of a planar electrode arranged on the display substrate and an edge of the display substrate is greater than a threshold.

Optionally, the threshold is 0.1 mm.

Optionally, the display substrate is an array substrate, and the planar electrode is a common electrode arranged on the array substrate; or the display substrate is a color filter substrate, and the planar electrode is a common electrode arranged on the color filter substrate.

The present disclose further provides in some embodiments a display panel including the display substrate as described above and an opposite substrate arranged opposite to the display substrate.

The present disclose further provides in some embodiments a display device including the display substrate as described above and a metal frame configured to surround the display panel.

### BRIEF DESCRIPTION OF THE DRAWINGS

In order to illustrate the technical solutions of the present disclosure in a clearer manner, the drawings desired for the present disclosure will be described hereinafter briefly. Obviously, the following drawings merely relate to some embodiments of the present disclosure, and based on these drawings, a person skilled in the art may obtain the other drawings without any creative effort.

FIG. 1 is a structure schematic diagram of a display panel in the related art;

FIG. 2 is a schematic diagram showing the display device before a metal frame of the display device being subjected to a force in the related art;

FIG. 3 is a schematic diagram showing the display device when the metal frame of the display device being subjected to the force in the related art;

FIG. 4 is a structure schematic diagram of a display panel according to an embodiment of the present disclosure;

FIG. 5 is a schematic diagram showing the display device before a metal frame of the display device being subjected to a force according to an embodiment of the present disclosure; and

FIG. 6 is a schematic diagram showing the display device when the metal frame of the display device being subjected to the force according to an embodiment of the present disclosure.

### DETAILED DESCRIPTION

In order to make the objects, the technical solutions and the advantages of the embodiments of the present disclosure more apparent, the present disclosure will be described hereinafter in a detailed manner in conjunction with the drawings and embodiments.

Currently, narrow frame of the TFT-LCD is a development trend. At present, the MDL (display module) segment frame is gradually narrowed. Metal frame will become more popular without changing the design of the display panel and ensuring the strength of the MDL. In the related art, a whole layer of a planar electrode is formed on the display substrate motherboard. After the display substrate motherboard is cut to form a display substrate, there are burrs on the planar electrode which has been cut at the edge of the display substrate. When the display device is pressed and collided, the burrs on the planar electrodes are easily to be in contact with the metal frame. As a result, the voltage applied to the planar electrode may be unstable, and an image displayed on the display device may be abnormal.

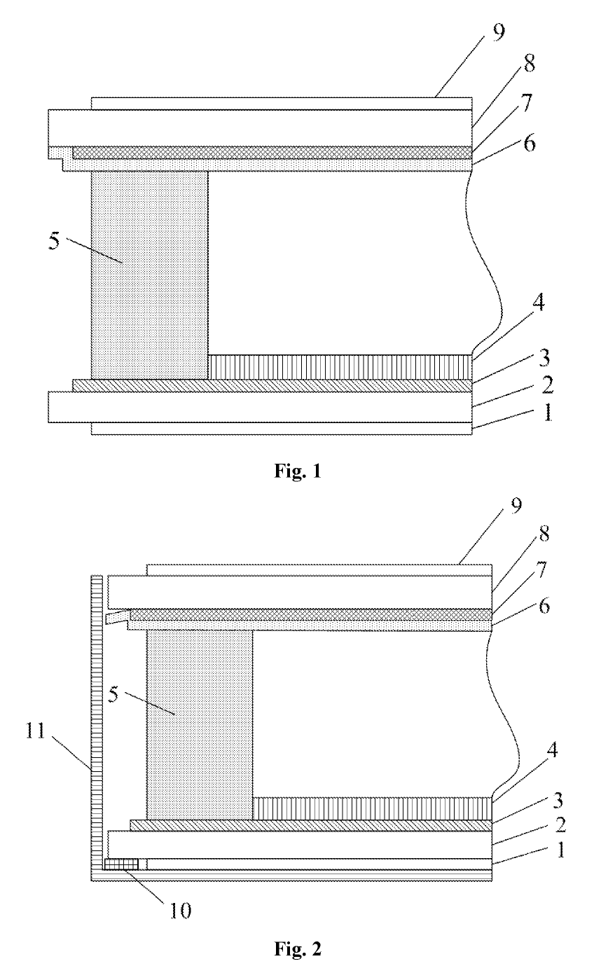

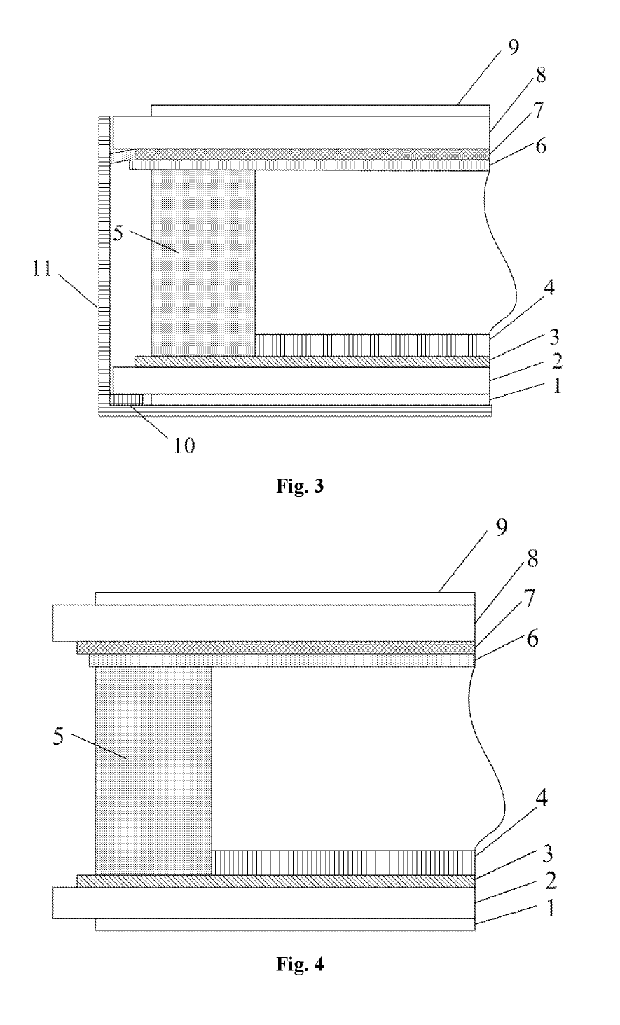

As shown in FIG. 1, for a Twisted Nematic (TN) type display panel, a whole layer of a common electrode 6 is formed on a base substrate 8 of a color filter substrate. Correspondingly, a whole layer of a planar electrode is formed on the color filter substrate motherboard. As shown in FIG. 2, after the color filter substrate motherboard is cut to form a color film substrate, there are burrs on the cut common electrode 6 at the edge of the color filter substrate. As shown in FIG. 3, when the display device is pressed and collided, the burrs of the planar electrodes are easily to be in contact with the metal frame. As a result, the voltage applied to the common electrode 6 is unstable, and thus an image displayed by the display device may be abnormal. Not only the common electrode, but also any whole layer of the planar electrode may have this problem. In order to solve the problem as described above, the present disclosure provides in some embodiments a display substrate motherboard and a method for manufacturing the display substrate motherboard, a display substrate, a display panel and a display device, which can stabilize the voltage applied to a planar electrode of the display device and ensure the display quality of the display device.

The present disclosure provides a method for manufacturing the display substrate motherboard, including: forming a planar electrode layer on the display substrate motherboard, performing a patterning process on the planar electrode layer, and removing a portion of the planar electrode layer to form a plurality of planar electrodes. The portion of the planar electrode layer is located around a predetermined cutting line for the display substrate motherboard, the plurality of planar electrodes is separated from each other, an edge of each of the planar electrodes is parallel to the predetermined cutting line, and a vertical distance between the edge of each of the planar electrodes and the predetermined cutting line is greater than a threshold.

In the embodiment, after forming a whole of a planar electrode layer on the display substrate motherboard; it performs a patterning process on the planar electrode layer, and removing a portion of the planar electrode layer to form a plurality of planar electrodes. The portion of the planar electrode layer is located around a predetermined cutting line for the display substrate motherboard, the plurality of planar electrodes is separated from each other, an edge of each of the planar electrodes is parallel to the predetermined cutting line, and a vertical distance between the edge of each of the planar electrodes and the predetermined cutting line is greater than a threshold. In this way, after the display substrate motherboard is cut to form the display substrate, the vertical distance between the planar electrode on the display substrate and the edge of the display substrate is greater than a threshold. Thus, even when the display device is pressed or collided, the metal frame of the display device may not contact the planar electrode of the display substrate. Therefore, it can stabilize the voltage applied to a planar electrode of the display device and ensure the display quality of the display device.

The display substrate motherboard can be a color filter substrate motherboard or an array substrate motherboard. The planar electrode can be a common electrode of the color filter substrate motherboard or the array substrate motherboard. For a TN type display panel, the common electrode is located on the color filter substrate; for a horizontal electric field type display panel, the common electrode is located on the array substrate. It should be appreciated that the planar electrode is not limited to a common electrode, and may also be of another type.

Optionally, an edge of each of the planar electrodes is parallel to the predetermined cutting line, and the vertical distance between the edge of each of the planar electrodes and the predetermined cutting line is greater than 0.1 mm. In this case, a sufficient distance between the edge of the planar electrode and the predetermined cutting line is maintained. Specifically, an edge of each of the planar electrodes is parallel to the predetermined cutting line, and the vertical distance between the edge of each of the planar electrodes and the predetermined cutting line is 0.15 mm.

The present disclosure provides in some embodiments a display substrate motherboard including a plurality of planar electrodes arranged on the display substrate motherboard. The plurality of planar electrodes is separated from each other. An edge of each of the planar electrodes is parallel to a predetermined cutting line for the display substrate motherboard, and a vertical distance between the edge of each of the planar electrodes and the predetermined cutting line is greater than a threshold.

In the embodiments, the plurality of planar electrodes is provided on the display substrate motherboard. The plurality of planar electrodes is separated from each other, an edge of each of the planar electrodes is parallel to the predetermined cutting line, and a vertical distance between the edge of each of the planar electrodes and the predetermined cutting line is greater than a threshold. In this way, after the display substrate motherboard is cut to form the display substrate, the vertical distance between the planar electrode on the display substrate and the edge of the display substrate is greater than a threshold. Thus, even when the display device is pressed or collided, the metal frame of the display device may not contact the planar electrode of the display substrate. Therefore, it can stabilize the voltage applied to a planar electrode of the display device and ensure the display quality of the display device.

The display substrate motherboard can be a color filter substrate motherboard or an array substrate motherboard. The planar electrode can be a common electrode of the color filter substrate motherboard or the array substrate motherboard. For a TN type display panel, the common electrode is located on the color filter substrate; for a horizontal electric field type display panel, the common electrode is located on the array substrate. It should be appreciated that the planar electrode is not limited to a common electrode, and may also be of another type.

Optionally, an edge of each of the planar electrodes is parallel to the predetermined cutting line, and the vertical distance between the edge of each of the planar electrodes and the predetermined cutting line is greater than 0.1 mm. In this case, a sufficient distance between the edge of the planar electrode and the predetermined cutting line is maintained. Specifically, an edge of each of the planar electrodes is parallel to the predetermined cutting line, and the vertical distance between the edge of each of the planar electrodes and the predetermined cutting line may be 0.15 mm.

The present disclosure provides in some embodiments a display substrate. A vertical distance between an edge of a planar electrode arranged on the display substrate and an edge of the display substrate is greater than a threshold.

In the embodiments of the present disclosure, the vertical distance between an edge of a planar electrode arranged on the display substrate and an edge of the display substrate is greater than a threshold. Thus, even when the display device including the display substrate is pressed or collided, the metal frame of the display device may not contact the planar electrode of the display substrate. Therefore, it can stabilize the voltage applied to a planar electrode of the display device and ensure the display quality of the display device.

The display substrate can be a color filter substrate or an array substrate. The planar electrode can be a common electrode of the color filter substrate or the array substrate. For a TN type display panel, the common electrode is located on the color filter substrate; and for a horizontal electric field type display panel, the common electrode is located on the array substrate. It should be appreciated that the planar electrode is not limited to a common electrode, and may also be of another type.

Optionally, the vertical distance between the edge of the planar electrode and the edge of the display substrate is greater than 0.1 mm. In this case, a sufficient distance between the edge of the planar electrode and edge of the display substrate is maintained, thereby preventing the planar electrode and the metal frame from being in contact with each other. Specifically, the vertical distance between the edge of the planar electrode and the edge of the display substrate may be 0.15 mm.

The present disclosure further provides in some embodiments a display panel including the display substrate as described above and an opposite substrate arranged opposite to the display substrate.

The present disclosure further provides in some embodiments a display device including the display substrate as described above and a metal frame configured to surround the display panel. The display device may be any product or component having a display function, such as a liquid crystal television, a liquid crystal display device, a digital photo frame, a mobile phone, a tablet computer, or the like. The display device may also include a flexible circuit board, a printed circuit board, and a backplane.

Hereinafter, the technical solution of the present disclosure will be described in details by taking the planar electrode as a common electrode on the color filter substrate as an example. When manufacturing the color filter substrate motherboard, it adds a patterning process, wherein a patterning process is performed on the common electrode layer on the color filter substrate motherboard, the planar electrode layer around the predetermined cutting line of the color filter substrate motherboard is removed, and a plurality of common electrodes being separated from each other are formed. And each common electrode is spaced apart from a predetermined cutting line by a certain distance. The common electrode is parallel to the predetermined cutting line. Thus, after the color filter substrate motherboard is cut to form a color film substrate, the common electrode on the color film substrate is spaced apart from the edge of the color film substrate by a certain distance, thereby preventing the common electrode from being exposed due to burrs formed after the cutting process is performed.

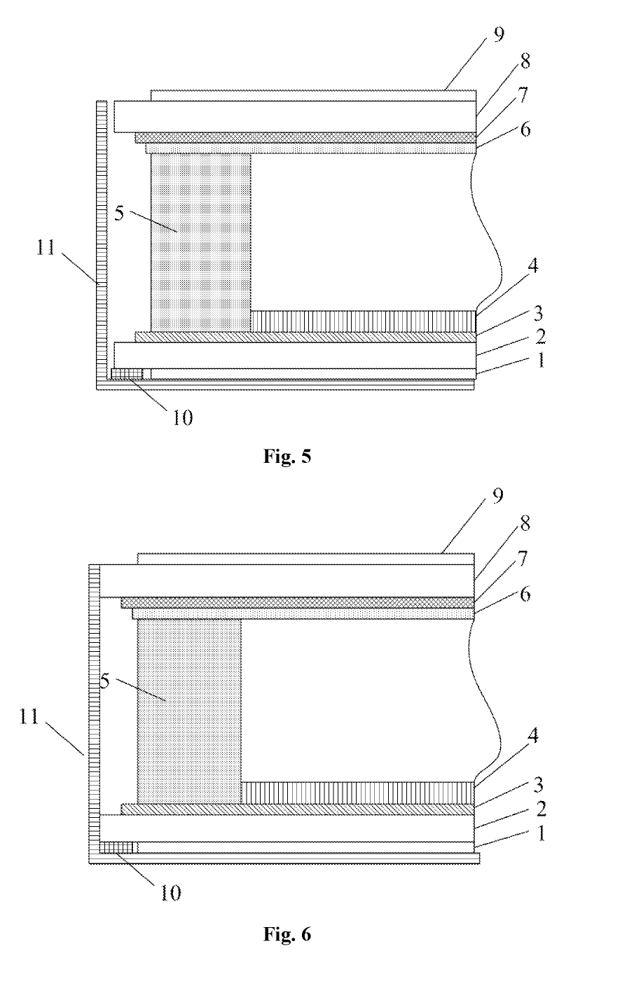

In the embodiments of the present disclosure, as shown in FIG. 4, the display panel includes the color filter substrate and the array substrate arranged opposite to the color filter substrate. A polarizer 9 is arranged on a side of the color filter substrate distal to the array substrate. A polarizer 1 is arranged on a side of the array substrate distal to the color filter substrate. The color filter substrate includes a base substrate 8 and a black matrix 7 and a common electrode 6 which are arranged on the base substrate 8. The array substrate includes a base substrate 2 and a gate metal layer 3 and a display film layer 4 which are located on the base substrate 2. The color filter substrate and the array substrate are packaged together by sealant 5. As shown in FIG. 5, the display device further includes a metal frame 11 configured to surround the display panel. A plastic support block 10 is arranged between the metal frame 11 and the base substrate 2.

It can be seen from FIG. 4 and FIG. 5 that, as compared with the common electrode 6 in FIG. 1 and FIG. 2, the edge of the common electrode 6 is contracted toward the inside of the display panel. The edge of the common electrode 6 is spaced apart from the edge of the color filter substrate by a certain distance, so that the metal frame 11 can be prevented from contacting the common electrode 6. As shown in FIG. 6, the common electrode 6 does not contact the metal frame 11 even if the display is pressed or collided. Therefore, it may prevent the voltage applied to the common electrode 6 from being adversely affected during the operation of the display device, so that it can stabilize the voltage applied to the common electrode and ensure the display quality of the display device.

The distance between the edge of the common electrode 6 and the edge of the color filter substrate is preferably greater than 0.1 mm. In this case, a sufficient distance between the edge of the common electrode 6 and edge of the color filter substrate is maintained, thereby preventing the common electrode 6 from being in contact with the metal frame 11. Specifically, the vertical distance between the edge of the common electrode and the edge of the color filter substrate may be 0.15 mm. It should be appreciated that the vertical distance between the edge of the common electrode 6 and the edge of the color filter substrate may alternatively be greater than 0.15 m; meanwhile, it should ensure that the contraction of the common electrode 6 does not adversely affect the operation of the display device, the edge of the common electrode 6 may not be located at an inner side of the sealant 5 after the common electrode 6 is contracted, and the common electrode 6 must be in contact with the sealant 5. Otherwise, the connection of the common electrode 6 and a wire on a side of the array substrate through conducting spheres in the sealant 5 will be adversely affected.

Unless otherwise defined, any technical or scientific term used herein shall have the common meaning understood by a person of ordinary skills. Such words as “first” and “second” used in the specification and claims are merely used to differentiate different components rather than to represent any order, number or importance. Similarly, such words as “comprising” or “including” are merely used to represent that an item or object presented prior to the word contains items or objects and equivalents enumerated subsequent to the word, without precluding a possibility of further containing other items or objects and equivalents. Such words as “connect/connected to” or “couple/coupled to” may include electrical connection, direct or indirect. Such words as “on”, “under”, “left” and “right” are merely used to represent relative position relationship, and when an absolute position of the object is changed, the relative position relationship will be changed too.

It should be understood that in the case that one element, such as a layer, a film, a region, a substrate or the like, is referred to be located “on” or “under” another element, that means the element can be “directly” located “on” or “under” the other element, or there may be a further middle element between the two elements.

The above are merely preferred embodiments of the present disclosure. Obviously, a person skilled in the art may make further modifications and improvements without departing from the spirit of the present disclosure, and these modifications and improvements shall also fall within the scope of the present disclosure.

1. A method for manufacturing a display substrate motherboard, comprising:
forming a planar electrode layer on the display substrate motherboard;
performing a patterning process on the planar electrode layer, and removing a portion of the planar electrode layer to form a plurality of planar electrodes,
wherein the portion of the planar electrode layer is located around a predetermined cutting line for the display substrate motherboard, the plurality of planar electrodes is separated from each other, an edge of each of the planar electrodes is parallel to the predetermined cutting line, and a vertical distance between the edge of each of the planar electrodes and the predetermined cutting line is greater than a threshold.

2. The method according to claim 1, wherein the threshold is 0.1 mm.

3. A display substrate motherboard, comprising:
a plurality of planar electrodes arranged on the display substrate motherboard, wherein the plurality of planar electrodes is separated from each other, an edge of each of the planar electrodes is parallel to a predetermined cutting line for the display substrate motherboard, and a vertical distance between the edge of each of the planar electrodes and the predetermined cutting line is greater than a threshold.

4. The display substrate motherboard according to claim 3, wherein the threshold is 0.1 mm.

5. The display substrate motherboard according to claim 3, wherein
the display substrate motherboard is an array substrate motherboard, and the planar electrodes are common electrodes arranged on the array substrate motherboard; or
the display substrate motherboard is a color filter substrate motherboard, and the planar electrodes are common electrodes arranged on the color filter substrate motherboard.

6. A display substrate, wherein a vertical distance between an edge of a planar electrode arranged on the display substrate and an edge of the display substrate is greater than a threshold.

7. The display substrate according to claim 6, wherein the threshold is 0.1 mm.

8. The display substrate according to claim 6, wherein
the display substrate is an array substrate, and the planar electrode is a common electrode arranged on the array substrate; or
the display substrate is a color filter substrate, and the planar electrode is a common electrode arranged on the color filter substrate.

9. A display panel, comprising:
the display substrate according to claim 6; and
an opposite substrate arranged opposite to the display substrate.

10. A display device, comprising:
the display substrate according to claim 9; and
a metal frame configured to surround the display panel.

11. The display panel according to claim 9, wherein the threshold is 0.1 mm.

12. The display panel according to claim 9, wherein
the display substrate is an array substrate, and the planar electrode is a common electrode arranged on the array substrate; or
the display substrate is an color filter substrate, and the planar electrode is a common electrode arranged on the color filter substrate.
